(19) United States
(12) Patent Application Publication
(10) Pub. No.: US 2007/0216022 A1
(43) Pub. Date: Sep. 20, 2007

(54) FIN STRUCTURE FOR A HEAT SINK

(76) Inventors: Gen-Ping Deng, Shenzhen (CN); Yi-Qiang Wu, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/308,279

(22) Filed: Mar. 15, 2006

(51) Int. Cl. H01L 23/34

(52) U.S. Cl. 257/706

(57) ABSTRACT

A heat sink includes a base adapted for absorbing heat from a heat-generating component, and a plurality of parallel fins having channels defined therebetween. Each of the fins includes a main body standing on the base. A row of protruding portions and openings is alternately arranged on the main body along a direction from a lateral side to an opposite lateral side of the heat sink. The protruding portions disturb and deflect an airflow flowing in the channels from the lateral side to the opposite side of the heat sink. The openings intercommunicate the channels with each other so that the airflow can flow from one of the channels to the other of the channels.

### FIELD OF THE INVENTION

The present invention relates generally to a heat sink, and more particularly to a heat sink having a plurality of fins to remove heat from an electronic heat-generating component, wherein the fins have an improved structure.

### DESCRIPTION OF RELATED ART

Heat sinks are usually used to remove heat from electronic heat-generating components, such as central processing units (CPUs) etc., to keep the components in stable operation. A typical heat sink comprises a base for contacting with the heat-generating component to absorb the heat of the heat-generating component and a plurality of parallel planar fins attached to the base by soldering or adhering. The fins are used for dissipating the heat to ambient air. For enhancing heat dissipation efficiency, a fan is usually mounted on a top or a side of the heat sink to impel air to flow between the fins.

To meet a requirement of heat removal from the heat-generating component which generates more and more heat, it is current way to enlarge the total outer area of the fins by increasing the number of the fins or enlarging a dimension of each fin. However, such thermal resolutions have their limitations. Because a space in a computer enclosure is crowded by various components and the space available for the heat sink cannot be readily increased, an increase of the size of the fins is not feasible. Furthermore, the larger number the fins have, the denser the fins are, and further the narrower the channels between the fins are. If the air channels are too narrow, the air cannot smoothly flow through the channels, which impedes the heat dissipation of the heat sink even if the number of the fins is increased.

What is needed is a heat sink in which has a great heat dissipating efficiency by means of improving heat exchange between the fins and air flowing through the heat sink under a condition that the size and number of the fins are not necessary to be increased.

### SUMMARY OF INVENTION

A heat sink in accordance with a preferred embodiment of the present invention comprises a base for absorbing heat from a heat-generating component, and a plurality of parallel fins having channels defined therebetween. Each of the fins comprises a main body standing on the base. A row of protruding portions and openings is arranged on the main body along a direction from one lateral side to an opposite lateral side of the heat sink. The protruding portions and the openings are alternately arranged. The protruding portions disturb and deflect an airflow flowing in the channels. The opening intercommunicates the channels with each other so that the airflow can flow from one of the channels to the other of the channels.

Other advantages and novel features will become more apparent from the following detailed description of preferred embodiments when taken in conjunction with the accompanying drawings, in which:

### BRIEF DESCRIPTION OF DRAWINGS

FIG. 1 is an isometric view of a heat sink in accordance with a preferred embodiment of the present invention, having a fin thereof separate from a base thereof; and

FIG. 2 is an isometric view of a heat sink in accordance with an alternative embodiment of the present invention, having a fin thereof separate from a base thereof.

### DETAILED DESCRIPTION

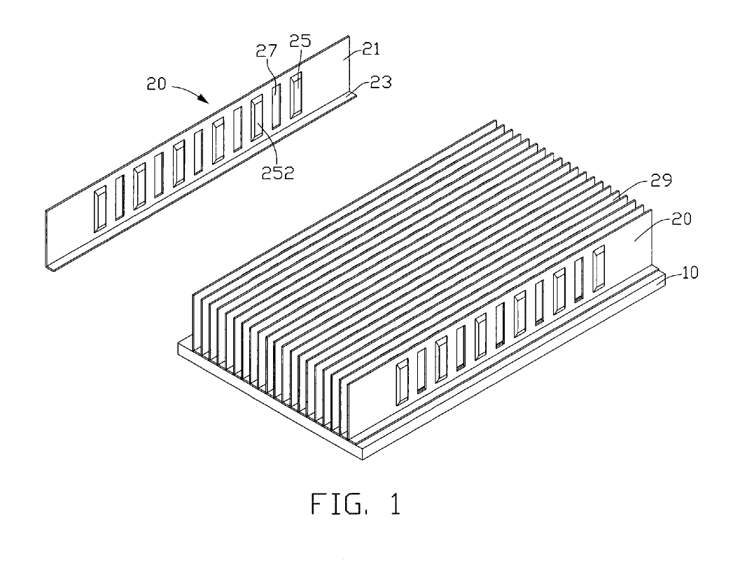

Referring to FIG. 1, a heat sink 1 in accordance with a preferred embodiment of the invention comprises a base 10 and a plurality of individual fins 20 which are stacked together and attached to the base 10 by any conventional means, such as soldering or adhering.

The base 10 is a flat heat conducting plate, and comprises a bottom surface (not shown) for absorbing heat from a heat-generating component (not shown) and a top surface (not labeled).

Each fin 20 comprises a main body 21 and a flange 23 bent perpendicular from a bottom edge of the main body 21. The flange 23 extends from a front face of each fin 20. A plurality of rectangular protruding portions 25 is formed on the main body 21 of each fin 20. The protruding portions 25 are stamped from a rear face of the main body 21 to the front face of the main body 21. Thus, the protruding portions 25 protrude from the front face of the main body 21 and depress at the rear face of the main body 21. A plurality of rectangular openings 27 is defined in the main body 21. The protruding portions 25 and the openings 27 are alternately and separately arranged on a substantially central portion of the main body 21 along a length direction of each fin 20. The protruding portions 25 and the openings 27 are lined in a row.

In an assembly of the heat sink 1, all of the flanges 23 of the fins 20 corporately define a coplanar plane which is attached to the top surface of the base 10 so that the fins 20 are mounted onto the top surface of the base 10 side by side to define a plurality of channels 29 therebetween. An airflow generated by a fan (not shown) enters the channels 29 from a lateral side of the heat sink 1 and leaves the channels 29 from an opposite lateral side of the heat sink 1. The protruding portions 25 and the openings 27 of each fin 20 are alternately arranged between the two opposite sides along the corresponding channel 29. The protruding portions 25 are disposed in the channels 29. The openings 27 make the channels 29 intercommunicated with each other. The protruding portions 25 each have a front wall 252 parallel to the main body 20.

In use of the heat sink 1, the base 10 absorbs heat from the heat-generating component and transfers the heat to the fins 20 because the flanges 23 of the fins 20 are attached on the top surface of the base 10 and thermally connect therewith. The heat is dissipated via the fins 20 to the ambient air. The fan (not shown) can be mounted at the side of the heat sink 1 to form the forced airflow through the heat sink 1. In the channels 29, the airflow impinges the protruding portions 25 and is deflected. The channels 29 are intercommunicated by the openings 27 and thus airflow can flow from one of the channels 29 to the other of the channels 29. Therefore, disturbance and turbulence of the airflow is formed. Heat transferred from the fins 20 to the airflow is increased, thereby to increase heat dissipation efficiency of the heat sink 1. Furthermore, the protruding portions 25 can increase a contact area between the airflow and the fins 20, thereby further enhancing the heat dissipation efficiency of the heat sink 1.

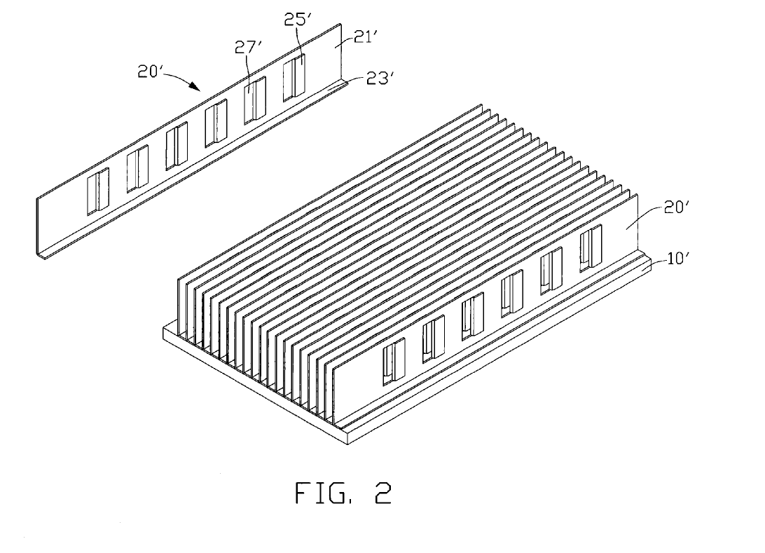

In an alternative embodiment as shown in FIG. 2, a heat sink 1′ comprises a base 10′ and a plurality of fins 20′. Each fin 20′ comprises a main body 21′ and a flange 23′. The flange 23′ is bent perpendicular from a bottom of the main body 21′ and is attached to the base 10′ by soldering. Rectangular protruding portions 25′ are punched forwardly from the main body 21′ of each fin 20′ and then bent laterally to be parallel to the main body 21′; accordingly, rectangular openings 27′ are defined in the main body 21′ by the punching and immediately adjacent to the protruding portions 25′, respectively. The protruding portions 25′ and the openings 27′ are alternately arranged on a substantially central portion of the main body 21′ along a length direction of each fin 20′. Other structure of the heat sink 1′ of this preferred embodiment is substantially the same as that of the heat sink 1 of the first embodiment and a description thereof can be referred to the first embodiment. The protruding portions 25′ function the same as the protruding portions 25 to deflect and distribute the airflow in the channels and increase the contact area between the fins 21′ and the airflow.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A heat sink comprising:
a base adapted for absorbing heat from a heat-generating component; and
a plurality of parallel fins having channels defined therebetween, each of the fins comprising a main body standing on the base, a row of protruding portions and openings alternately arranged on the main body along a direction from a lateral side to an opposite lateral side of the heat sink, the lateral side being adapted as an entrance of an airflow into the channels, and the opposite lateral side being adapted as an exit of the airflow out of the channels, the openings intercommunicating the channels with each other, the protruding portions projecting into the channels.

2. The heat sink as claimed in claim 1, wherein each of the fins comprises a flange extending from the main body of a corresponding fin, and wherein the flanges of the fins are attached to the base.

3. The heat sink as claimed in claim 2, wherein the flanges define a distance between the fins when the flanges are attached to the base.

4. The heat sink as claimed in claim 2, wherein the flange is perpendicular to the main body.

5. The heat sink as claimed in claim 1, wherein the protruding portions are stamped from a first face of each fin to an opposite second face of said each fin, each protruding portion having a front wall in front of the second face of said each fin and parallel to the main body of said each fin.

6. The heat sink as claimed in claim 1, wherein the protruding portions are punched from a first face of each fin to an opposite second face of said fin, whereby the openings are defined in the main body by the punching and located immediately adjacent to the protruding portions, respectively.

7. The heat sink as claimed in claim 6, wherein the protruding portions are bent laterally to be parallel to the main body after being punched.

8. The heat sink as claimed in claim 1, wherein the protruding portions and the openings are rectangular.

9. A heat sink comprising:
a base adapted for absorbing heat from a heat-generating component; and
a plurality of fins mounted on the base, the fins defining a plurality of channels therebetween, a plurality of protruding portions being arranged in the channels for disturbing and deflecting an airflow flowing in the channels, a plurality of openings being defined in the fins, the openings intercommunicating the channels with each other so that the airflow can flow from one of the channels to the other of the channels, the protruding portions and the openings being alternately arranged on the fins along a direction, the airflow flowing through the channels along the direction.

10. The heat sink as claimed in claim 9, wherein the protruding portions each protrude from a first face of a corresponding fin and depress at an opposite second face of the corresponding fin.

11. The heat sink as claimed in claim 9, wherein the protruding portions are punched from the fins and bent laterally to be parallel to the fins.

12. The heat sink as claimed in claim 9, wherein the protruding portions and the openings are lined in a row at each of the fins.

13. The heat sink as claimed in claim 12, wherein the protruding portions and the openings are separate from each other.

14. The heat sink as claimed in claim 12, wherein the openings are immediately adjacent to corresponding protruding portions, respectively.

15. The heat sink as claimed in claim 9, wherein the protruding portions and the openings are alternately arranged between two opposite lateral sides of the heat sink.

16. A fin for a heat sink for dissipating heat from an electronic component, comprising:
a main body;
a plurality of openings defined in the main body; and
a plurality protrusions formed on the main body, each of the protrusions having a portion parallel to the main body; wherein
the openings and the protrusions are alternately arranged on the main body along a lengthwise direction of the main body.

17. The fin as claimed in claim 16, wherein the protrusions are spaced from the openings respectively with a distance.

18. The fin as claimed in claim 17, wherein the main body has a lateral side and an opposite lateral side, the protrusions and the openings being arranged along a direction from the lateral side to the opposite lateral side, a front face between the two lateral sides, the portion of each of the protrusions parallel to the main body being in front of the front face of the main body.

19. The fin as claimed in claim 18 further comprising a flange extending perpendicularly from a bottom of the main body for being soldered to a base of the heat sink.

20. The fin as claimed in claim 16, wherein the protrusions are immediately adjacent to the openings, respectively, with the protrusions being formed by punching the main body to obtain the openings, the protrusions being bent towardone of the two opposite lateral sides of the main body.
